(19) United States
(12) Patent Application Publication
(10) Pub. No.: US 2025/0102335 A1
(43) Pub. Date: Mar. 27, 2025

(54) AIRFLOW SENSOR AND AIRFLOW SENSOR PACKAGING STRUCTURE

(71) Applicant: Memsensing Microsystems (Suzhou, China) Co., Ltd., Suzhou (CN)

(72) Inventor: Yanzi MENG, Suzhou (CN)

(73) Assignee: Memsensing Microsystems (Suzhou, China) Co., Ltd., Suzhou (CN)

(21) Appl. No.: 18/895,572

(22) Filed: Sep. 25, 2024

(30) Foreign Application Priority Data
Sep. 26, 2023 (CN) 202311252149.4

(51) Int. Cl. G01F 1/58

(52) U.S. Cl. CPC G01F 1/584

(57) ABSTRACT

Disclosed an airflow sensor and an airflow sensor packaging structure. The airflow sensor comprises at least one pressure equalizing structure, and a pressure equalizing structure is physically isolated from a gap layer, so that a continuous flow path is established between a back cavity of the airflow sensor and a space outside the airflow sensor. The airflow sensor also comprises a air release channel that passes through the gap between the fixed electrode and the vibrating electrode. The gap layer is connected to the space outside the airflow sensor through the air release channel.

### CROSS-REFERENCE TO RELATED APPLICATIONS

This application claims the benefit of China Patent Application No. 202311252149.4, filed with the China National Intellectual Property Administration on Sep. 26, 2023 and entitled “AIRFLOW SENSOR AND AIRFLOW SENSOR PACKAGING STRUCTURE”, the disclosures of which are incorporated by reference herein in their entirety.

### TECHNICAL FIELD

The present invention relates to the technical field of airflow sensor, and more specifically, to an airflow sensor and an airflow sensor packaging structure.

### BACKGROUND

Devices manufactured based on Micro-Electro-Mechanical System (MEMS) are called MEMS devices and the device of the MEMS capacitive pressure sensor comprises a diaphragm and a back-pole plate, and there is a gap between the diaphragm and the back-pole plate. A change in air pressure causes deformation of the diaphragm and a change in the capacitance value between the diaphragm and the back-pole plate, which is converted to an electrical signal output.

For applications in airflow sensors, when the airflow sensor senses the user's inhalation, the diaphragm of the airflow sensor deforms, converting the air pressure on both sides of the diaphragm of the airflow sensor into changes in the internal capacitance of the sensor to output a signal, thus the airflow sensor can be used as a switch to control the atomizer of electronic cigarettes. The existing electronic cigarettes generate negative pressure when the user inhales, causing the diaphragm to deform under the negative pressure. The chip of the Application Specific Integrated Circuit (ASIC) detects the capacitance change of the MEMS and triggers the cigarette lighting action. However, in the process of use, sometimes there is a blowback phenomenon, that is, when the diaphragm of the airflow sensor is subjected to positive pressure, the diaphragm is deformed, and when the diaphragm returns to the equilibrium position from the deformed position, the ASIC detects the change in capacitance and triggers the action of cigarette lighting.

However, if the blowback time is relatively short, the cigarette lighting action will not be triggered; otherwise, the cigarette lighting action will be triggered.

### SUMMARY

The present invention aims to solve at least one of the technical problems existing in the prior art and provide an airflow sensor and an airflow sensor packaging structure.

The purpose of the present invention is achieved by the following technical solutions:

According to a first aspect of the present invention, an airflow sensor is provided, wherein the airflow sensor comprises:
a substrate, a vibrating electrode, and a fixed electrode disposed in a laminated arrangement, the substrate having a first cavity passing through the substrate in a thickness direction thereof;
the vibrating electrode has a vibration-sensitive area, and a gap layer is disposed between the vibration-sensitive area and the fixed electrode, the vibrating electrode and the fixed electrode form a variable capacitor;
the airflow sensor further comprises at least one pressure equalizing structure, the pressure equalizing structure comprises a pressure equalizing hole and a pressure equalizing channel, the pressure equalization hole being disposed at a perimeter edge of a vibration-sensitive area of the vibrating electrode, and the pressure equalizing channel being connected with the pressure equalizing hole to establish a continuous flow path in a space outside the airflow sensor and the first cavity;
wherein the pressure equalizing structure is physically isolated from the gap layer, the airflow sensor further comprises an air release channel passing through the gap between the fixed electrode and the vibrating electrode, the gap layer being connected to the space outside the airflow sensor through the air release channel.

According to a second aspect of the present invention, an airflow sensor packaging structure is provided, wherein the airflow sensor packaging structure comprises a base plate, a housing and the above-mentioned airflow sensor;
the base plate is fixedly connected to the housing to form a cavity, and the airflow sensor is fixedly connected to a side surface of the base plate facing the housing and is disposed in the cavity;
a first through-hole is disposed on the base plate, a second through-hole is disposed on the housing, the airflow sensor covers the first through-hole, the airflow sensor separates the cavity into at least a first cavity and a second cavity, the first cavity is connected to the first through-hole, the second cavity is connected to the external environment through the second through-hole, and the first cavity is connected to the second cavity through the pressure equalizing structure.

The airflow sensor and the airflow sensor packaging structure provided by the present invention are intended to establish a continuous flow path between the first cavity of the airflow sensor and the space outside the airflow sensor by providing at least one pressure equalizing structure on the airflow sensor and physically isolating the pressure equalizing structure from the gap layer. The airflow sensor also comprises the air release channel that passes through the gap between the fixed electrode and the vibrating electrode. The gap layer is connected to the space outside the airflow sensor through the air release channel. Therefore, not only can the ASIC connected to the airflow sensor be prevented from detecting a differential pressure signal in a non-working state, thereby causing false triggering of other components.

It can also reduce the diffusion (invasion) of pollutants (e.g., cigarette oil, etc.) from the space outside the airflow sensor into the gap layer, thus perfectly solving the problem of film absorption caused by contaminants (such as cigarette oil, etc.) between the vibrating electrode and the back-pole plate, as well as the problem of false triggering and short-circuiting that may be caused by the pollutants therefrom.

### BRIEF DESCRIPTION OF THE DRAWINGS

To describe technical solutions in embodiments of this application more clearly, the following briefly introduces the accompanying drawings for describing the embodiments. It is clear that the accompanying drawings in the following descriptions show merely some embodiments of this application, and a person skilled in the art may still derive other drawings from these accompanying drawings without creative efforts.

FIG. 1A is a cross-sectional view in a main view direction of an airflow sensor, according to a first embodiment of the present invention;

FIG. 1B is a top view of the airflow sensor, according to the embodiment in FIG. 1A.

FIG. 2A is a cross-sectional view in a main view direction of the airflow sensor, according to a second embodiment of the present invention;

FIG. 2B is a top view of the airflow sensor, according to the embodiment in FIG. 2A;

FIG. 3A is a cross-sectional view in the main view direction of the airflow sensor, according to a third embodiment of the present invention;

FIG. 3B is a top view of the airflow sensor, according to the embodiment in FIG. 3A;

FIG. 4 is a cross-sectional view in the main view direction of the airflow sensor, according to a fourth embodiment of the present invention;

FIG. 5 is a cross-sectional view in the main view direction of an airflow sensor packaging structure, according to an embodiment of the present invention.

### DETAILED DESCRIPTION

The above description is only an overview of the technical solution of the present invention, in order to be able to more clearly understand the technical means of the present invention, and can be implemented in accordance with the contents of the specification, and in order to make the above and other purposes, features and advantages of the present invention can be more obvious and easy to understand, the following specially cites some embodiments and with the accompanying drawings, the following is described in detail.

In the description of the present invention, it should be noted that unless otherwise specified and limited, terms such as “set,” “connect,” and “attach” should be broadly interpreted. For example, it can be a fixed connection or a detachable connection, or even an integral connection. It can be a mechanical connection, an electrical connection, or a communicative connection. It can be directly connected or indirectly connected through an intermediate medium. It can refer to either internal communication between two components or the interaction between the two components. Ordinary technicians in this field can understand the specific meanings of the above-mentioned terms in the present invention based on specific circumstances.

At least one embodiment of the present application provides an airflow sensor 2. The airflow sensor 2 comprises: a substrate 10, a vibrating electrode 30, and a fixed electrode 50 disposed in a laminated arrangement, the substrate 10 having a first cavity 11 passing through the substrate 10 in a thickness direction thereof.

The vibrating electrode 30 has a vibration-sensitive area, and a gap layer 42 is disposed between the vibration-sensitive area and the fixed electrode 50, the vibrating electrode 30 and the fixed electrode 50 form a variable capacitor.

The airflow sensor 2 further comprises at least one pressure equalizing structure, the pressure equalizing structure comprises a pressure equalizing hole 31 and a pressure equalizing channel 43, the pressure equalization hole being disposed at a perimeter edge of a vibration-sensitive area of the vibrating electrode 30, and the pressure equalizing channel 43 being connected with the pressure equalizing hole 31 to establish a continuous flow path in a space outside the airflow sensor 2 and the first cavity 11.

Wherein the pressure equalizing structure is physically isolated from the gap layer 42, the airflow sensor 2 further comprises an air release channel 41 passing through the gap between the fixed electrode 50 and the vibrating electrode 30, the gap layer 42 being connected to the space outside the airflow sensor 2 through the air release channel 41.

As can be seen from the above, the embodiment of the present application are intended to establish a continuous flow path between the first cavity 11 of the airflow sensor 2 and the space outside the airflow sensor 2 by providing at least one pressure equalizing structure on the airflow sensor 2 and physically isolating the pressure equalizing structure from the gap layer 42. And the pressure equalizing hole 31 is disposed at a non-sensitive region of the vibrating electrode 30. Thereby, pressure equalization between the surface of the side of the vibrating electrode 30 toward the first cavity 11 and the surface of the side of the vibrating electrode 30 away from the first cavity 11 is achieved in a non-working state. The ASIC connected to the airflow sensor 2 is prevented from detecting a differential pressure signal that causes false triggering of other components.

The airflow sensor 2 also comprises the air release channel 41 that passes through the gap between the fixed electrode 50 and the vibrating electrode 30. The gap layer 42 is connected to the space outside the airflow sensor 2 through the air release channel 41. It can also reduce the diffusion (invasion) of pollutants (e.g., cigarette oil, etc.) from the space outside the airflow sensor 2 into the gap layer 42, thus perfectly solving the problem of film absorption caused by contaminants (such as cigarette oil, etc.) between the vibrating electrode 30 and the back-pole plate, as well as the problem of false triggering and short-circuiting that may be caused by the pollutants therefrom.

### Embodiment 1

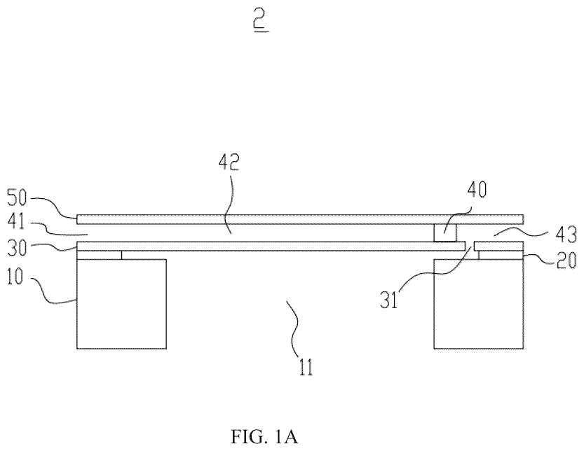

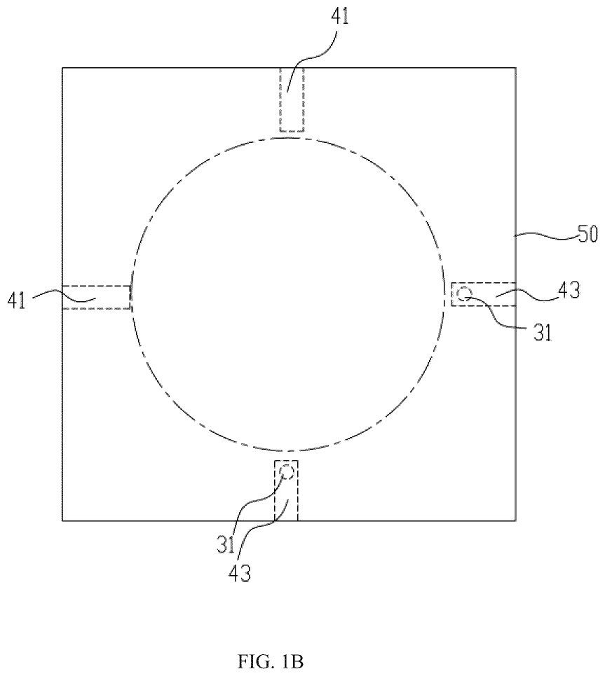

FIG. 1A is a cross-sectional view in a main view direction of an airflow sensor 2, according to a first embodiment of the present invention;

FIG. 1B is a top view of the airflow sensor 2, according to the embodiment in FIG. 1A.

As shown in FIG. 1A and FIG. 1B, the airflow sensor 2 comprises: a substrate 10, a vibrating electrode 30, and a fixed electrode 50 disposed in a laminated arrangement, the substrate 10 having a first cavity 11 passing through the substrate 10 in a thickness direction thereof.

The vibrating electrode 30 has a vibration-sensitive area, and a gap layer 42 is disposed between the vibration-sensitive area and the fixed electrode 50, the vibrating electrode 30 and the fixed electrode 50 form a variable capacitor.

The airflow sensor 2 further comprises at least one pressure equalizing structure, the pressure equalizing structure comprises a pressure equalizing hole 31 and a pressure equalizing channel 43, the pressure equalization hole being disposed at a perimeter edge of a vibration-sensitive area of the vibrating electrode 30, and the pressure equalizing channel 43 being connected with the pressure equalizing hole 31 to establish a continuous flow path in a space outside the airflow sensor 2 and the first cavity 11.

Wherein the pressure equalizing structure is physically isolated from the gap layer 42, the airflow sensor 2 further comprises an air release channel 41 passing through the gap between the fixed electrode 50 and the vibrating electrode 30, the gap layer 42 being connected to the space outside the airflow sensor 2 through the air release channel 41.

In the embodiment of the present application, it is intended to establish a continuous flow path between the first cavity 11 of the airflow sensor 2 and the space outside the airflow sensor 2 by providing at least one pressure equalizing structure on the airflow sensor 2 and the pressure equalizing structure being physically isolated from the gap layer 42, so as to not only equalize the pressure between the surface of the side of the vibrating electrode 30 toward the first cavity 11 and the surface of the side of the vibrating electrode 30 away from the first cavity 11 in a non-working state to prevent the airflow sensor 2 from being triggered incorrectly. The airflow sensor 2 also comprises the air release channel 41 passing through the gap between the fixed electrode 50 and the vibrating electrode 30, the gap layer 42 being connected to the space outside the airflow sensor 2 through the air release channel 41, which also reduces the diffusion (invasion) of pollutants (e.g., cigarette oil, etc.) from the space outside the airflow sensor 2 into the gap layer 42, thus perfectly solving the problem of film absorption caused by contaminants (such as cigarette oil, etc.) between the vibrating electrode 30 and the back-pole plate, as well as the problem of false triggering and short-circuiting that may be caused by the pollutants therefrom.

In some embodiments, a first support body 20 is formed between the vibrating electrode 30 and the substrate 10 to connect a portion of the the vibrating electrode 30 with a portion of the substrate 10, and a second support body 40 is formed between the fixed electrode 50 and the vibrating electrode 30 to connect a portion of the fixed electrode 50 with a portion of the vibrating electrode 30.

In a direction perpendicular to the thickness direction of the substrate 10, the air release channel 41 passes through the second support body 40.

In the embodiments of the present application, both the first support body 20 and the second support body 40 are insulating support bodies, such as silicon oxide or silicon nitride. The thickness of the first support body 20 and the second support body 40 is between 2˜3 um, for example, around 2.5 um. The vibrating electrode 30 and the fixed electrode 50 are opposed to each other and arranged at an insulating distance, so that an oscillation cavity for the vibrating electrode 30 to vibrate is formed between the fixed electrode 50 and the vibrating electrode 30, that is, a gap layer 42 as shown in FIG. 1A is formed.

In some embodiments, the first support body 20 is located at the edge of the base to support the vibrating electrode 30, so that the vibrating electrode 30 is suspended above the first cavity 11. Specifically, the vibrating electrode 30 includes a vibration-sensitive area and a support area, wherein the support area suspends the vibrating electrode 30 above the first cavity 11 through the first support body 20. The second support body 40 is disposed at the edge of the vibrating electrode 30 such that the fixed electrode 50 is suspended above the vibrating electrode 30 and spaced from the vibrating electrode 30 to provide insulation. It should be noted that the vibrating electrode 30 in this embodiment is a planar membrane structure located directly above the first cavity 11. Generally, the vibrating electrode 30 deforms when acted upon by an external force. The amount of deformation of the vibrating electrode 30 (the magnitude of deformation of the vibrating electrode 30) decreases sequentially along the direction of the vibrating electrode 30's geometric center outwardly.

It should be understood that in embodiments of the present invention, the air release channel 41 passes through the second support body 40 in a direction perpendicular to the thickness direction of the substrate 10. Specifically, the air release channel 41 can be formed by etching part of the second support body 40 at the connection between the vibrating electrode 30 and the fixed electrode 50 to form a gap.

In some embodiments, the fixed electrode 50 is a single-layer structure, and the entire of the fixed electrode 50 serves as a conductive electrode to form a variable capacitor between the vibrating electrode 30. In other embodiments, the fixed electrode 50 can also be a multi-layer structure, which comprises at least one conductive layer 601. The conductive layer 601 of the fixed electrode 50 forms a variable capacitor between the vibrating electrode 30. Embodiments of the present invention are not limited herein.

In this embodiment, the pressure equalizing structure comprises the pressure equalizing hole 31 and the pressure equalizing channel 43. The pressure equalizing hole 31 is provided at the perimeter edge of the vibration-sensitive area of the vibrating electrode 30, the pressure equalizing channel 43 is disposed in the gap between the fixed electrode 50 and the vibrating electrode 30. The pressure equalizing channel 43 is connected with the pressure equalizing hole 31 to establish a continuous flow path between the first cavity 11 of the airflow sensor 2 and a space outside of the airflow sensor 2. Thereby, realizing that in the non-working state, the side surface of the vibrating electrode 30 facing the first cavity 11 and the side surface of the vibrating electrode 30 away from the first cavity 11 are connected. Pressure equalization to prevent the ASIC connected to the airflow sensor 2 from detecting capacitance changes, causing false triggering of other components.

In some embodiments, the whole of the pressure equalizing structure is L-shaped. When the airflow of the electronic cigarette enters from the first cavity 11 of the airflow sensor 2, the airflow of the electronic cigarette acts on the vibrating electrode 30, causing the vibrating electrode 30 to deform, and the airflow of the electronic cigarette can be discharged to the external space of the airflow sensor 2 through the equalizing pressure hole on the vibrating electrode 30. In this embodiment, the second support body 40 adjacent to the pressure equalizing hole 31 may form a side wall for blocking contaminants (cigarette oil, etc.) entering through the pressure equalizing hole 31 from diffusing (invading) into the gap layer 42 through the pressure equalizing hole 31, thereby completely solving the problem of film absorption due to contaminants (cigarette oil, etc.) of the vibrating electrode 30 and the fixed electrode 50.

It should be noted that in the process of making the airflow sensor 2, thousands of release holes are usually disposed on the fixed electrode 50, and the thousands of release holes are uniformly distributed on the fixed electrode 50 for removing the sacrificial layer between the fixed electrode 50 and the vibrating electrode 30 by the solution release method. In the embodiment of the present application, after the sacrificial layer is released between the fixed electrode 50 and the vibrating electrode 30 to form the gap layer 42, it is necessary to close the above-mentioned release holes. However, since the airflow sensor 2 also comprises the air release channel 41 passing through the gap between the fixed electrode 50 and the vibrating electrode 30, the gap layer 42 is connected to the space outside the airflow sensor 2 through the air release channel 41 to achieve air pressure balance. Therefore, no air release channel 41 connected to the gap layer 42 is disposed on the fixed electrode 50, in other words, all of the above-mentioned release holes may be closed, so that the effective area of the fixed electrode 50 facing the vibrating electrode 30 can also be increased to a certain extent.

In some embodiments, the number of the air release channel 41 is less than or equal to 10. For example, the number of the air release channel 41 can be 2, 3, 5, 6, or 8. No further discussion will be made herein.

Compared with the thousands of release holes provided on the fixed electrode 50, and the uniformly distributed arrangement of all release holes on the fixed electrode 50, the technical solution provided by the embodiment of the present application can also significantly increase the effective overlapping area of the fixed electrode 50 and the vibrating electrode 30, which can increase the size of the variable capacitor of the airflow sensor 2 without changing the size of the airflow sensor 2 itself, thereby improving the detection sensitivity of the airflow sensor 2.

In some embodiments, the pressure equalizing channel 43 passes through the gap between the fixed electrode 50 and the vibrating electrode 30; the air outlet of the pressure equalizing channel 43 is disposed at the gap between the fixed electrode 50 and the vibrating electrode 30. Thereby, the flow direction of the gas containing contaminants (e.g., cigarette oil, etc.) discharged from the outlet of the pressure equalizing passage is completely different from the direction of the air outlet of the pressure equalizing structure. Further, the probability of the gas containing contaminants (e.g., cigarette oil, etc.) entering into the gap layer 42 from the air release channel 41 is reduced, and the service life of the product is improved.

### Embodiment 2

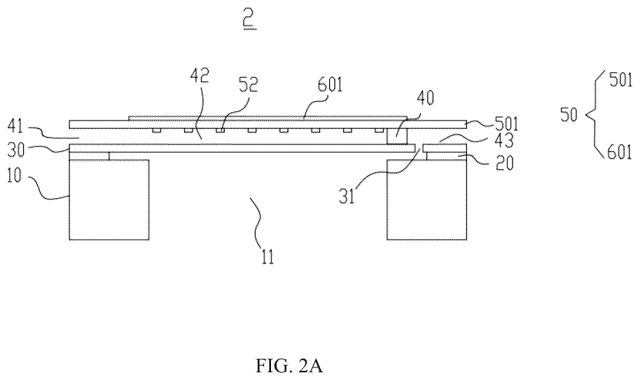

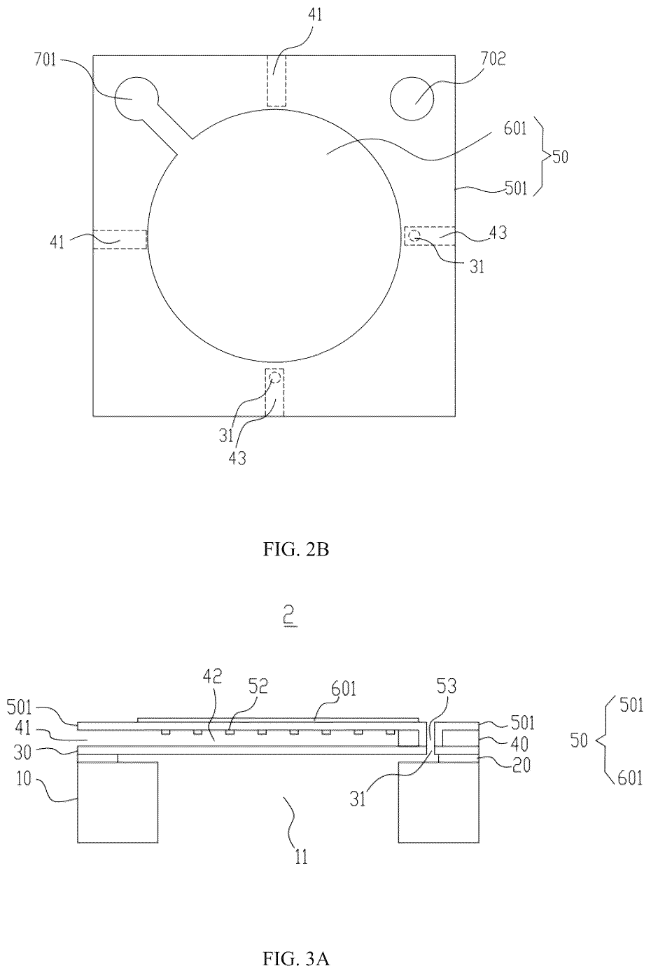

FIG. 2A is a cross-sectional view in a main view direction of the airflow sensor 2, according to a second embodiment of the present invention; FIG. 2B is a top view of the airflow sensor 2, according to the embodiment in FIG. 2A.

As shown in FIG. 2A and FIG. 2B, the difference between FIG. 2A and FIG. 1A is that in this embodiment the fixed electrode 50 comprises an insulating layer 501 and a conductive layer 601 fixedly connected to the insulating layer 501, the conductive layer 601 is disposed on a side of the insulating layer 501 away from the vibrating electrode 30 in a thickness direction of the substrate 10, and a projection of the conductive layer 601 is within a projection of a vibration-sensitive area.

In this embodiment, the pressure equalizing structure comprises the pressure equalizing hole 31 and the pressure equalizing channel 43. The pressure equalizing hole 31 is disposed at the perimeter edge of the vibration-sensitive area of the vibrating electrode 30, and the pressure equalizing channel 43 passes through the gap between the insulating layer 501 of the fixed electrode 50 and the vibrating electrode 30. The pressure equalizing channel 43 is connected to the pressure equalizing hole 31 to establish a continuous flow path in the first cavity 11 of the airflow sensor 2 and the space outside the airflow sensor 2.

Similar to the embodiment 1, in this embodiment, no air release channel 41 connected to the gap layer 42 is disposed on the fixed electrode 50. The number of the air release channel 41 is less than or equal to 10. To reduce the probability of the gas containing contaminants (e.g., cigarette oil, etc.) entering into the gap layer 42 from the air release channel 41, thereby improving the service life of the product.

In this embodiment, the airflow sensor 2 further comprises a first pad 701 and a second pad 702. The first pad 701 is electrically connected to the conductive layer 601 of the fixed electrode 50, and is configured to transmit an electrical signal of the conductive layer 601. The second pad 702 is electrically connected to the vibrating electrode 30, and is configured to transmit an electrical signal of the vibrating electrode 30.

Further, in order to prevent the problem of adhesion caused by film absorption between the fixed electrode 50 and the vibrating electrode 30, an anti-adhesive structure 52 is provided on the surface of the side of the fixed electrode 50 facing the vibrating electrode 30, so as to prevent the adhesion caused by film absorption between the fixed electrode 50 and the vibrating electrode 30.

Optionally, the anti-adhesive structure 52 and the insulating layer 501 on the fixed electrode 50 are integrally formed.

### Embodiment 3

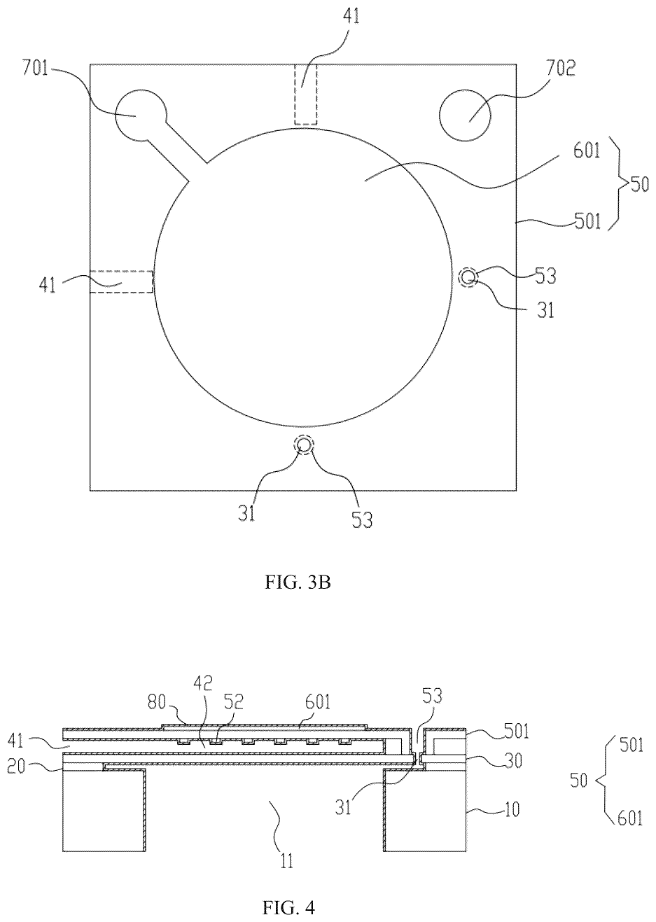

FIG. 3A is a cross-sectional view in the main view direction of the airflow sensor 2, according to a third embodiment of the present invention; FIG. 3B is a top view of the airflow sensor 2, according to the embodiment in FIG. 3A.

As shown in FIG. 3A and FIG. 3B, what is different from Embodiment 1 and Embodiment 2 is that in this embodiment, the pressure equalizing channel 43 comprises a through-hole 53 disposed on the fixed electrode 50, and the through-hole 53 is connected to the vibrating electrode 30. The pressure equalizing hole 31s are connected to form the pressure equalizing structure.

In some embodiments, the through-hole 53 may be formed by etching the second support body 40 in the thickness direction. A positive projection of the through-hole 53 on the substrate 10 overlaps with a positive projection of the pressure equalizing hole 31 on the substrate 10 such that the pressure equalizing structure forms an “I-shaped” connectivity in the thickness direction of the substrate 10. When the airflow of the electronic cigarette enters from the first cavity 11, the pressure equalizing structure establishes a continuous flow path in the space outside the first cavity 11 and the airflow sensor 2, so that in the non-working state, the vibrating electrode 30 can also move toward the first cavity 11. The pressure of the side surface of the vibrating electrode 30 is balanced with the side surface of the vibrating electrode 30 away from the first cavity 11 to prevent the airflow sensor 2 from being falsely triggered.

In some embodiments, the side wall of the pressure equalizing channel 43 (through-hole 53) adjacent to the gap layer 42 is covered with an isolation structure. The isolation structure and the insulating layer 501 on the fixed electrode 50 are integrally formed. That is, the side wall of the through-hole 53 may be covered by the insulating layer 501 of the fixed electrode 50, thereby forming a pressure equalizing channel 43 with the insulating layer 501, which is jointly used to block the diffusion (intrusion) of an airflow containing a contaminant (e.g., cigarette oil, etc.) into the gap layer 42 between the vibrating electrode 30 and the fixed electrode 50.

What is different from Embodiment 1 and Embodiment 2 is that in this embodiment, the air outlet of the pressure equalizing channel is disposed on the fixed electrode 50. In this embodiment, by arranging the pressure equalizing hole 31 and the air release channel 41 at a certain angle. For example, the pressure equalizing hole 31 and the air release channel 41 are arranged diagonally. So as to reduce the probability of the gas containing contaminants (e.g., cigarette oil, etc.) discharged to the external space of the airflow sensor 2 via the pressure equalizing hole 31s will be ejected into the gap layer 42 from the air release channel 41, thereby improving the service life of the product. It should be understood that in the embodiment of the present application, as long as the distance between the pressure equalizing hole 31 and the air release channel 41 is as far as possible, the relative positional relationship between the pressure equalizing hole 31 and the air release channel 41 is not strictly limited.

### Embodiment 4

FIG. 4 is a cross-sectional view in the main view direction of the airflow sensor 2, according to a fourth embodiment of the present invention.

As shown in FIG. 4, in some embodiments, what is different from the previous embodiment is that airflow sensor 2 comprises the oleophobic layer 80 (80), which is disposed on the surface of the vibrating electrode 30 and the fixed electrode 50 and covers the side walls of the pressure equalizing hole 31, the pressure equalizing channel 43 and the air release channel 41.

The oleophobic layer 80 (80), for example the oleophobic layer 80 (80) made use of self-assembled monolayer (SAM) material, makes a thin oleophobic layer 80 (80) on all layers. When pollutants (e.g., cigarette oil, etc.) enter into the gap layer 42, aggregation may occur on the surface of the vibrating electrode 30s without causing the vibrating electrode 30s and the fixed electrode 50s to be absorbed, at which time the airflow sensor 2 in the electronic cigarettes will not fail during operation. Further, an oleophobic layer 80 (80) may be added to other structures, for example, the sidewalls of the first cavity 11 of the substrate 10 are also coated with an oleophobic layer 80 (80), which may further minimize the adhesion of the fixed electrode 50 and the vibrating electrode 30, and reduce the failure rate of the product.

### Embodiment 5

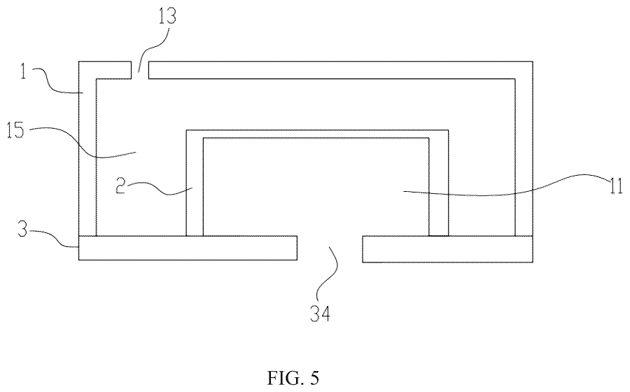

FIG. 5 is a cross-sectional view in the main view direction of an airflow sensor packaging structure, according to an embodiment of the present invention.

As shown in FIG. 5, according to a second aspect of the present application, an airflow sensor packaging structure is provided. The airflow sensor packaging structure comprises a base plate 3, a housing 1 and the above-mentioned airflow sensor 2. The base plate 3 is fixedly connected to the housing 1 to form a cavity, and the airflow sensor 2 is fixedly connected to a side surface of the base plate 3 facing the housing 1 and is disposed in the cavity. A first through-hole 34 is disposed on the base plate 3, a second through-hole 13 is disposed on the housing 1. The airflow sensor 2 covers the first through-hole 34, the airflow sensor 2 separates the cavity into at least a first cavity 11 and a second cavity 15, the first cavity 11 is connected to the first through-hole 34, so as to allow the airflow of the electronic cigarette to enter through the first cavity 11 of the airflow sensor 2. The second cavity 15 is connected to the external environment through the second through-hole 13, and the first cavity 11 is connected to the second cavity 15 through the pressure equalizing structure, so as to sense a pressure difference between the external environment of the airflow sensor packaging structure and the corresponding first through-hole 34 of the airflow sensor packaging structure.

The airflow sensor 2 and the airflow sensor packaging structure provided by the present invention are intended to establish a continuous flow path between the first cavity 11 of the airflow sensor 2 and the space outside the airflow sensor 2 by providing at least one pressure equalizing structure on the airflow sensor 2 and physically isolating the pressure equalizing structure from the gap layer 42. The airflow sensor 2 also comprises the air release channel 41 that passes through the gap between the fixed electrode 50 and the vibrating electrode 30. The gap layer 42 is connected to the space outside the airflow sensor 2 through the air release channel 41. Therefore, not only can the ASIC connected to the airflow sensor 2 be prevented from detecting a differential pressure signal in a non-operating state, thereby causing false triggering of other components.

It can also reduce the diffusion (invasion) of pollutants (e.g., cigarette oil, etc.) from the space outside the airflow sensor 2 into the gap layer 42, thus perfectly solving the problem of film absorption caused by contaminants (such as smoke oil, etc.) between the vibrating electrode 30 and the back-pole plate, as well as the problem of false triggering and short-circuiting that may be caused by the pollutants therefrom.

In some embodiments, a first support body 20 is formed between the vibrating electrode 30 and the substrate 10 to connect a portion of the the vibrating electrode 30 with a portion of the substrate 10, and a second support body 40 is formed between the fixed electrode 50 and the vibrating electrode 30 to connect a portion of the fixed electrode 50 with a portion of the vibrating electrode 30;
in a direction perpendicular to the thickness direction of the substrate 10, the air release channel 41 passes through the second support body 40.

In some embodiments, the number of the air release channel 41 is less than or equal to 10.

In some embodiments, no air release channel (41) connected to the gap layer (42) is disposed on the fixed electrode (50).

In some embodiments, the fixed electrode 50 comprises an insulating layer 501 and a conductive layer 601 fixedly connected to the insulating layer 501, the conductive layer 601 is disposed on a side of the insulating layer 501 away from the vibrating electrode 30 in a thickness direction of the substrate 10, and a projection of the conductive layer 601 is within a projection of a vibration-sensitive area.

In some embodiments, the pressure equalizing channel 43 passes through the gap between the fixed electrode 50 and the vibrating electrode 30; the air outlet of the pressure equalizing channel 43 is disposed at the gap between the fixed electrode 50 and the vibrating electrode 30.

In some embodiments, the pressure equalizing channel 43 comprises a through-hole 53 disposed in the fixed electrode 50, the through-hole 53 being connected to the pressure equalizing hole 31.

In some embodiments, the air outlet of the pressure equalizing channel 43 is disposed on the fixed electrode 50.

In some embodiments, the side wall of the pressure equalizing channel 43 adjacent to the gap layer 42 is covered with an isolation structure.

In some embodiments, the isolation structure and the insulating layer 501 on the fixed electrode 50 are integrally formed.

In some embodiments, an anti-adhesive structure 52 is disposed on a surface of a side of the fixed electrode 50 toward the vibrating electrode 30.

In some embodiments, the anti-adhesive structure 52 and the insulating layer 501 on the fixed electrode 50 are integrally formed.

In some embodiments, the oleophobic layer 80 (80) is disposed on the surface of the vibrating electrode 30 and the fixed electrode 50 and covers the side walls of the pressure equalizing hole 31, the pressure equalizing channel 43 and the air release channel 41.

The above embodiments are intended to illustrate the technical solution of this application rather than limiting it. Although detailed descriptions have been provided with reference to the aforementioned embodiments, those skilled in the art should understand that modifications can still be made to the technical solutions described in the aforementioned embodiments, or equivalent substitutions can be made for some technical features. Such modifications or substitutions should not depart from the essence, spirit, and scope of the technical solutions of the embodiments of the present invention.

1. An airflow sensor, wherein the airflow sensor (2) comprises:
a substrate (10), a vibrating electrode (30), and a fixed electrode (50) disposed in a laminated arrangement, the substrate (10) having a first cavity (11) passing through the substrate (10) in a thickness direction thereof;
the vibrating electrode (30) has a vibration-sensitive area, and a gap layer (42) is disposed between the vibration-sensitive area and the fixed electrode (50), the vibrating electrode (30) and the fixed electrode (50) form a variable capacitor;
the airflow sensor (2) further comprises at least one pressure equalizing structure, the pressure equalizing structure comprises a pressure equalizing hole (31) and a pressure equalizing channel (43), the pressure equalization hole being disposed at a perimeter edge of a vibration-sensitive area of the vibrating electrode (30), and the pressure equalizing channel (43) being connected with the pressure equalizing hole (31) to establish a continuous flow path in a space outside the airflow sensor (2) and the first cavity (11);
wherein the pressure equalizing structure is physically isolated from the gap layer (42), the airflow sensor (2) further comprises an air release channel (41) passing through the gap between the fixed electrode (50) and the vibrating electrode (30), the gap layer (42) being connected to the space outside the airflow sensor (2) through the air release channel (41).

2. The airflow sensor according to claim 1, wherein a first support body (20) is formed between the vibrating electrode (30) and the substrate (10) to connect a portion of the the vibrating electrode (30) with a portion of the substrate (10), and a second support body (40) is formed between the fixed electrode (50) and the vibrating electrode (30) to connect a portion of the fixed electrode (50) with a portion of the vibrating electrode (30);
in a direction perpendicular to the thickness direction of the substrate (10), the air release channel (41) passes through the second support body (40).

3. The airflow sensor according to claim 2, wherein the number of the air release channel (41) is less than or equal to 10.

4. The airflow sensor according to claim 1, wherein no air release channel (41) connected to the gap layer (42) is disposed on the fixed electrode (50).

5. The airflow sensor according to claim 4, wherein the fixed electrode (50) comprises an insulating layer (501) and a conductive layer (601) fixedly connected to the insulating layer (501), the conductive layer (601) is disposed on a side of the insulating layer (501) away from the vibrating electrode (30) in a thickness direction of the substrate (10), and a projection of the conductive layer (601) is within a projection of a vibration-sensitive area.

6. The airflow sensor according to claim 2, wherein the pressure equalizing channel (43) passes through the gap between the fixed electrode (50) and the vibrating electrode (30);
the air outlet of the pressure equalizing channel (43) is disposed at the gap between the fixed electrode (50) and the vibrating electrode (30).

7. The airflow sensor according to claim 5, wherein the pressure equalizing channel (43) comprises a through-hole (53) disposed in the fixed electrode (50), the through-hole (53) being connected to the pressure equalizing hole (31).

8. The airflow sensor according to claim 7, wherein the air outlet of the pressure equalizing channel (43) is disposed on the fixed electrode (50).

9. The airflow sensor according to claim 7, wherein the side wall of the pressure equalizing channel (43) adjacent to the gap layer (42) is covered with an isolation structure.

10. The airflow sensor according to claim 9, wherein the isolation structure and the insulating layer (501) on the fixed electrode (50) are integrally formed.

11. The airflow sensor according to claim 5, wherein an anti-adhesive structure (52) is disposed on a surface of a side of the fixed electrode (50) toward the vibrating electrode (30).

12. The airflow sensor according to claim 11, wherein the anti-adhesive structure (52) and the insulating layer (501) on the fixed electrode (50) are integrally formed.

13. The airflow sensor according to claim 1, wherein the airflow sensor (2) further comprises an oleophobic layer (80), the oleophobic layer (80) is disposed on the surface of the vibrating electrode (30) and the fixed electrode (50) and covers the side walls of the pressure equalizing hole (31), the pressure equalizing channel (43) and the air release channel (41).

14. An airflow sensor packaging structure, wherein the airflow sensor packaging structure comprises a base plate (3), a housing (1) and the airflow sensor (2) according to claim 1;
the base plate (3) is fixedly connected to the housing (1) to form a cavity, and the airflow sensor (2) is fixedly connected to a side surface of the base plate (3) facing the housing (1) and is disposed in the cavity;
a first through-hole (34) is disposed on the base plate (3), a second through-hole (13) is disposed on the housing (1), the airflow sensor (2) covers the first through-hole (34), the airflow sensor (2) separates the cavity into at least a first cavity (11) and a second cavity (15), the first cavity (11) is connected to the first through-hole (34), the second cavity (15) is connected to the external environment through the second through-hole (13), and the first cavity (11) is connected to the second cavity (15) through the pressure equalizing structure.
